(19) United States
(12) Patent Application Publication
(10) Pub. No.: US 2022/0316051 A1
(43) Pub. Date: Oct. 6, 2022

(54) MASK

(71) Applicants: Chengdu BOE Optoelectronics Technology Co., Ltd., Chengdu (CN); BOE Technology Group Co., Ltd., Beijing (CN)

(72) Inventors: Lirui YAN, Beijing (CN); Rong JIN, Beijing (CN); Chuan SHI, Beijing (CN); Jikun PENG, Beijing (CN); Duanming LI, Beijing (CN)

(21) Appl. No.: 17/508,874

(22) Filed: Oct. 22, 2021

(30) Foreign Application Priority Data
Mar. 30, 2021 (CN) 202110337573.3

(51) Int. Cl. C23C 16/04; H01L 51/56

(52) U.S. Cl. CPC C23C 16/042; H01L 51/56

(57) ABSTRACT

The mask includes: a mask body provided with a shielding part configured to shield an IC region between two adjacent panels sharing a base substrate; and the shielding part includes a reinforcing portion and a thinned portion, and the thinned portion has an accommodating recess with an opening facing the base substrate to be configured to accommodate a driving IC in the IC region.

### CROSS REFERENCE TO RELATED APPLICATIONS

This disclosure is based on and claims priority under 35 U.S.C 119 to Chinese Patent Application No. 202110337573.3, filed on Mar. 30, 2021, in the China National Intellectual Property Administration. The entire disclosure of the above application is incorporated herein by reference.

### FIELD

The disclosure relates to the technical field of display, in particular to a mask.

### BACKGROUND

Plasma deposition technology is generally used in a packaging process of flexible organic light-emitting diode (Oled) devices. While a mask used in the plasma deposition is an important factor affecting the packaging effect.

At present, in order to avoid scratching IC circuit portion of a panel formed by the plasma deposition technology, a glass contact surface of a CVD Mask adopts a half-etching process for the entire mask. However, in this process, due to the half-etching design, the mechanical properties of an etched part of the above-mentioned mask are relatively poor, and the phenomenon of curling deformation easily occurs, resulting in a gap between the etched part of the mask and a glass substrate and ultimately reducing yield.

### SUMMARY

The disclosure provides a mask, which at least can improve the mechanical properties of an etched part to ensure that the etched part is not prone to being deformed and curled in the manufacturing process.

The mask provided by embodiments of the disclosure includes: a mask body, wherein the mask body is provided with a shielding part configured to shield an IC region between two adjacent panels sharing a base substrate. The shielding part includes a thinned portion and a reinforcing portion connected to the thinned portion, and the thinned portion has an accommodating recess with an opening facing the base substrate to be configured to accommodate a driving IC.

In some embodiments, the reinforcing portion and the mask body form an integrated structure.

In some embodiments, a side surface, facing the base substrate, of the reinforcing portion is flush with an end surface, facing the base substrate, of a side wall of the accommodating recess.

In some embodiments, a thickness of the reinforcing portion is the same as a thickness of the mask body.

In some embodiments, a depth of the accommodating recess is 5%-65% of a thickness of the mask body.

In some embodiments, the depth of the accommodating recess is 5%-30% of the thickness of the mask body.

In some embodiments, the reinforcing portion includes a first reinforcing rib disposed in a first direction.

In some embodiments, the reinforcing portion includes a plurality of second reinforcing ribs disposed in a second direction.

In some embodiments, the first reinforcing rib and the second reinforcing ribs are perpendicular to each other.

In some embodiments, a cross section shape of the accommodating recess is a circle, a rectangle or an ellipse.

Embodiments provide an OLED panel manufactured by using the above mask.

### BRIEF DESCRIPTION OF THE DRAWINGS

FIG. 1 is a schematic structural diagram of a mask according to embodiments of the disclosure.

FIG. 2 is a front view of a shielding part in a mask according to embodiments of the disclosure.

FIG. 3 is another front view of a shielding part in a mask according to embodiments of the disclosure.

### REFERENCE SIGNS

10—Mask body; 20—Shielding part; 21—Reinforcing portion; 22—Thinned portion; 220—Accommodating recess.

### DETAILED DESCRIPTION

The technical solutions of embodiments of the present disclosure will be described clearly and completely in combination with the accompanying drawings of the embodiments of the present disclosure. Apparently, the described embodiments are some, but not all, embodiments of the present disclosure. Based on the embodiments of the present disclosure, all other embodiments attainable by those ordinarily skilled in the art without involving any inventive effort are within the protection scope of the present disclosure.

In order to facilitate the understanding of the disclosure, a shielding part in embodiments of the disclosure is an etched part.

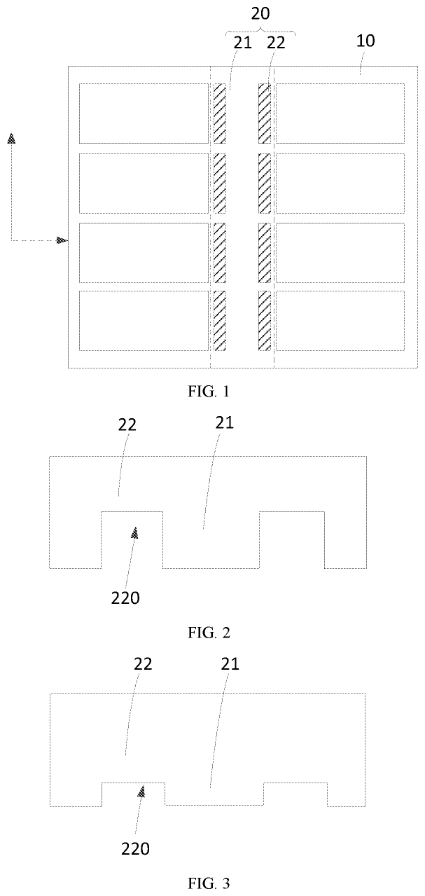

Referring to FIGS. 1 to 3, embodiments of the disclosure provides a mask, including a mask body 10 provided with a shielding part 20 configured to shield an IC region between two adjacent panels. The adjacent panels share one base substrate.

The shielding part 20 includes a reinforcing portion 21 and a thinned portion 22. The thinned portion 22 is provided with an accommodating recess 220. The accommodating recess 220 has an opening facing a base substrate to be configured to make room for a driving IC in the IC region.

The mask in the disclosure includes the mask body 10, the mask body 10 is provided with the shielding part 20. The shielding part 20 shields the IC region between the two adjacent panels. In some embodiments, the shielding part 20 includes the reinforcing portion 21 and the thinned portion 22. The thinned portion is provided with the accommodating recess 220 with the opening facing the base substrate, where the accommodating recess 220 corresponds to the driving IC in the IC region, so that the mask body 10 is prevented from scratching the driving IC in the packaging process. In addition, the arrangement of the reinforcing portion 21 can improve the mechanical properties of the mask in the shielding part 20 and reduce the possibility of curling and deformation in the manufacturing process.

It should be noted that when the reinforcing portion 21 is provided, the reinforcing portion 21 may be disposed on the side, facing away from the panels, of the accommodating recess 220 as long as the mechanical properties of the mask in the shielding part 20 is improved.

In some embodiments, in order to make the mechanical properties of the mask in the shielding part 20 higher, the reinforcing portion 21 and the mask body 10 may be designed as an integral structure.

In some embodiments, the side surface, facing the base substrate, of the reinforcing portion 21 is flush with an end surface, facing the base substrate, of a side wall of the accommodating recess 220. As such, when the mask body 10 is placed on a glass substrate, adhesion between the mask body 10 and the substrate is better.

In a direction of connecting two adjacent panels, a length of the side surface, facing towards the base substrate, of the reinforcing portion 21 may also be greater than a length of the side surface, facing towards the base substrate, of the side wall of the accommodating recess 220. As such, the part, facing towards one side of the base substrate, of the reinforcing part 21 is located in the accommodating recess 220. Such design can also ensure the mechanical properties of the mask in the shielding part 20 on the mask body 10.

In some embodiments, a thickness of the reinforcing portion 21 is the same as a thickness of the mask body 10, so that the overall flatness of the mask body 10 can be better, and the mask body is conveniently stacked with other devices.

In some embodiments, referring to FIG. 2, a depth of the accommodating recess 220 is 5%-65% of the thickness of the mask body 10. The depth of the accommodating recess 220 is set to be 5%-65% of a depth of the mask body 10 so as to improve the effect of the accommodating recess 220 accommodating the driving IC. In some embodiments, at least part of the reinforcing portion 21 is disposed in the accommodating recess 220 so as to divide the accommodating recess 220 into at least two parts, and each part of the accommodating recess 220 corresponds to the driving IC. Due to the reinforcing portion 21, it can be ensured that when the depth of the accommodating recess 220 is 5%-65%, the mechanical properties of the mask in the shielding part 20 can meet the requirements, to allow the mask to be not prone to being deformed and curled in the manufacturing process.

It should be noted that, referring to FIG. 3, in order to further improve the mechanical properties of the mask in the shielding part 20, the depth of the accommodating recess 220 may be reduced to increase the thickness of the thinned portion, to allow the mechanical properties of the mask in the shielding part 20 to be increased, and the risk of deformation of the mask body 10 in the manufacturing process to be reduced. In some embodiments, the depth of the accommodating recess 220 may be 5%-30% of the thickness of the mask body 10.

In some embodiments, the reinforcing portion 21 may include a first reinforcing rib disposed in a first direction, while the first direction is a direction indicated by a solid arrow in FIG. 1. The first reinforcing rib divides the accommodating recess 220 into two sub accommodating rooms, each sub accommodating room may correspond to driving ICs on a plurality of panels, and the mask body 10 is prevented from scratching the driving ICs.

It should be noted that the first direction may also be inclined, and the first reinforcing rib may also divide the accommodating recess 220 into two sub accommodating rooms as long as the two sub accommodating rooms correspond to the driving ICs and the driving ICs on each panel may correspond to the corresponding sub accommodating rooms.

In some embodiments, the reinforcing portion 21 may include a second reinforcing rib disposed in a second direction, and the second direction is in a direction indicated by a dashed arrow in FIG. 1. There can be a plurality of second reinforcing ribs, and the plurality of second reinforcing ribs may be disposed in the accommodating recess 220 so as to enhance the mechanical properties of the mask in the shielding part 20. The plurality of second reinforcing ribs may divide the accommodating recess 220 into a plurality of sub accommodating rooms, each sub accommodating room may correspond to the IC region formed between two oppositely-disposed panels, the driving IC in each IC region correspond to the sub accommodating rooms, and then the mask body 10 is prevented from scratching the driving ICs.

It should be noted that the plurality of second reinforcing ribs may be arranged in parallel, and the plurality of second reinforcing ribs may be arranged obliquely. At this time, the plurality of sub accommodating rooms formed by dividing the accommodating recess 220 through the plurality of second reinforcing ribs only need to correspond to the respective driving ICs.

In some embodiments, the reinforcing portion 21 may include a first reinforcing rib and a plurality of second reinforcing ribs. The first reinforcing rib is disposed in a first direction, the second reinforcing ribs are disposed in a second direction, and the first direction and the second direction are perpendicular, that is, the first reinforcing rib and the plurality of second reinforcing ribs are perpendicular. At this time, the first reinforcing rib and the plurality of second reinforcing ribs are also located in the accommodating recess 220. The arrangement of the first reinforcing rib and the second reinforcing ribs can improve the mechanical strength of the accommodating room, so that the mask body 10 is not prone to being deformed in the manufacturing process. In addition, the first reinforcing rib and the plurality of second reinforcing ribs divide the accommodating recess 220 into a plurality of sub accommodating rooms, and each sub accommodating room may correspond to one driving IC on the corresponding panel to prevent the mask body 10 from scratching the driving IC.

It should be noted that when the plurality of second reinforcing ribs are perpendicular to the first reinforcing rib, the plurality of sub accommodating rooms formed by dividing the accommodating recess 220 through the first reinforcing rib and the plurality of second reinforcing ribs may be rectangular. The sub accommodating rooms may also be in other shapes, which are not listed here.

In some embodiments, the cross section shape of the accommodating recess is a circle, a rectangle or an ellipse. The cross section shape of the accommodating recess may also be a trapezoid or a rhombus, etc., which will not be listed here. In an example embodiment, the cross section shape is rectangle.

Embodiments of the disclosure provide an OLED panel manufactured by using the mask according to any embodiments above. In an example embodiment, in the packaging process to obtain an OLED panel, the above mask is used during plasma deposition.

It will be apparent to those skilled in the art that various modifications and variations can be made in the embodiments of the present disclosure without departing from the spirit or scope of the present disclosure. Thus, it is intended that the present disclosure covers the modifications and variations of the present disclosure provided they come within the scope of the appended claims and their equivalents.

1. A mask, comprising:
a mask body; and
a shielding part on the mask body;
wherein
the shielding part is configured to shield an IC region between two adjacent panels sharing a base substrate;
the shielding part comprises a thinned portion and a reinforcing portion connected to the thinned portion; and
the thinned portion has an accommodating recess with an opening facing the base substrate to be configured to accommodate a driving IC in the IC region.

2. The mask according to claim 1, wherein the reinforcing portion and the mask body form an integrated structure.

3. The mask according to claim 2, wherein a side surface, facing the base substrate, of the reinforcing portion is flush with an end surface, facing the base substrate, of a side wall of the accommodating recess.

4. The mask according to claim 3, wherein a thickness of the reinforcing portion is same as a thickness of the mask body.

5. The mask according to claim 1, wherein a depth of the accommodating recess is 5%-65% of a thickness of the mask body.

6. The mask according to claim 5, wherein the depth of the accommodating recess is 5%-30% of the thickness of the mask body.

7. The mask according to claim 1, wherein the reinforcing portion comprises a first reinforcing rib disposed in a first direction.

8. The mask according to claim 7, wherein the reinforcing portion further comprises a plurality of second reinforcing ribs disposed in a second direction.

9. The mask according to claim 8, wherein the first reinforcing rib and the second reinforcing ribs are perpendicular to each other.

10. The mask according to claim 1, wherein a cross section shape of the accommodating recess is a circle, a rectangle or an ellipse.

11. The mask according to claim 1, wherein a side surface, facing the base substrate, of the reinforcing portion is flush with an end surface, facing the base substrate, of a side wall of the accommodating recess.

12. An OLED panel, manufactured by using the mask according to claim 1.
